(19) United States
(12) Patent Application Publication
(10) Pub. No.: US 2015/0351531 A1
(43) Pub. Date: Dec. 10, 2015

(54) Smartphone or tablet mounting device and method

(71) Applicant: Michael T. Dalton, Blairsville, GA (US)

(72) Inventor: Michael T. Dalton, Blairsville, GA (US)

(21) Appl. No.: 14/739,498

(22) Filed: Jun. 15, 2015

Related U.S. Application Data
(63) Continuation of application No. 13/722,579, filed on Dec. 20, 2012, now abandoned.
(60) Provisional application No. 61/578,635, filed on Dec. 21, 2011.

(51) Int. Cl. A47B 23/00; F16B 7/10; F16B 1/00; F16M 13/02; H05K 5/02; F16C 11/06

(52) U.S. Cl. CPC A47B 23/007; H05K 5/0204; A47B 23/00; F16C 11/0604; F16B 1/00; F16M 13/022; F16B 7/10; F16B 2001/0035

(57) ABSTRACT

A mounting apparatus for reversibly attaching a portable electronic device to a support surface, wherein the mounting apparatus comprises a support shaft, a connector device, a mounting attachment, and a mounting bracket. The connector device is secured to a first end of the support shaft for reversibly attaching the mounting apparatus to the support surface. The mounting attachment is secured to a second end of the support shaft, wherein the mounting attachment comprises a ball joint and a first locking device. The mounting bracket is secured to the mounting attachment for reversibly attaching the portable electronic device, wherein the mounting bracket comprises a second locking device. The first locking device and the second locking device are operable to reversibly fasten to each other with the ball joint therebetween so that the mounting bracket is rotatably secured to the mounting attachment.

This is a continuation of application Ser. No. 13/722,579 filed Dec. 20, 2012 which claimed priority from provisional application 61/578,635 filed Dec. 21, 2011. Applications Ser. No. 13/722,579 and 61/578,635 are hereby incorporated by reference in their entireties.

### FIELD OF THE INVENTION

The present invention is related to a portable mounting apparatus used to support an electronic device, and more particularly, to a mounting apparatus that can be quickly and reversibly attached to various surfaces, such as vertical and horizontal surfaces, to conveniently support an electronic device for viewing.

### BACKGROUND OF THE INVENTION

Hand-held electronic devices such as smart phones, electronic tablets, e-book readers, and the like are well known and widely used. There have been several accessories created for hands free use of these hand-held electronic devices. It would be particularly useful to have an accessory that would allow attachment of a hand-held electronic device to a surface (e.g. ceiling) for convenient viewing and/or listening. Conventional mounting systems are complex and typically require permanent mounting to a surface. What is needed is a quick-release mount that suspends or projects lightweight hand-held electronic devices at any height and angle, and which can be attached and removed quickly from any surface. Such a design would allow for top surface mounts, under counter mounts, wall mounts, and ceiling mounts.

### SUMMARY OF THE INVENTION

The present invention is a mounting apparatus for reversibly attaching a portable electronic device to a support surface, wherein the mounting apparatus comprises a support shaft, a connector device, a mounting attachment, and a mounting bracket. The support shaft may be telescoping. The connector device is secured to a first end of the support shaft for reversibly attaching the mounting apparatus to the support surface. The mounting attachment is secured to a second end of the support shaft, wherein the mounting attachment comprises a ball joint and a first locking device. The mounting bracket is secured to the mounting attachment for reversibly attaching the portable electronic device, wherein the mounting bracket comprises a second locking device. The first locking device and the second locking device are operable to reversibly fasten to each other with the ball joint therebetween so that the mounting bracket is rotatably secured to the mounting attachment. The connector device preferably comprises a magnet and the support surface preferably comprises a magnetically interactive material such that the magnet is operable to reversibly attach to the magnetically interactive support surface. In alternate embodiments, the connector device comprises a first coupling mechanism and the support surface comprises a mating second coupling mechanism such that the first coupling mechanism is operable to reversibly attach to the second coupling mechanism.

These and other features of the invention will become apparent from the following detailed description of the invention.

### BRIEF DESCRIPTION OF THE DRAWINGS

FIG. 1 shows an exploded perspective view of a preferred embodiment of the present invention.

FIG. 2 shows the top end of the embodiment of FIG. 1 assembled.

FIG. 3 shows the top end of the embodiment of FIG. 1 secured to a magnetically interactive support surface.

FIG. 4 shows the top end of an alternate embodiment secured to a support surface having a coupling mechanism.

FIG. 5 shows the top end of an alternate embodiment secured to a support surface having a coupling mechanism.

FIG. 6 shows a perspective view of a magnet holder.

FIG. 7 shows a perspective view of a magnet holder having a magnet therein.

FIG. 8 shows a perspective view of a threaded lock connector.

FIG. 9 shows a dual ball joint device secured to a support shaft.

FIG. 10 shows an alternate embodiment support shaft.

FIG. 11 shows an alternate embodiment support shaft with triangular end bases.

FIG. 12 shows an alternate view of the embodiment of FIG. 11.

FIG. 13 shows an alternate embodiment of a connector base.

FIG. 14 shows an alternate embodiment of a mounting attachment.

### DETAILED DESCRIPTION OF THE INVENTION

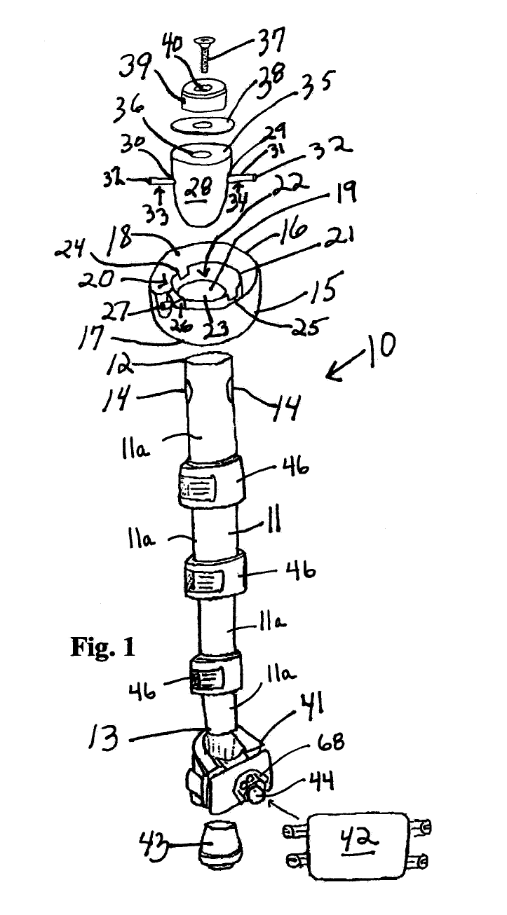

The preferred embodiments of the present invention are shown in FIGS. 1-14, wherein FIG. 1 shows an exploded view of the quick-release mount 10 of the present invention. Mount 10 has a support shaft (monopod) 11 which may be of fixed length or variable length. Shaft 11 is shown in FIG. 1 with a plurality of telescoping sections 11a securable to each other with a plurality of thumb tab locks 46. The length is adjustable, preferably, from 21 inches to 67 inches. The shaft 11 has a first end 12 and a second opposite end 13, and has holes 14 on opposite sides of shaft 11 near first end 12. A hanger ball 15 can be positioned slidably onto shaft 11 and placed below holes 14. Hanger ball 15 has a top end 16, a bottom end 17, a top opening 18, a bottom opening 19, and an interior 20. A container 21 may be fixed within the interior 20 of hanger ball 15 and encircle bottom opening 19. Container 21 has an interior 22, a top opening 23, and a first slot 24 and a second slot 25 on opposite sides and at the top 23 of container 21. Hanger ball 15 has a screw mount 26 with a screw 27 which passes through the wall of container 21 to engage shaft 11 so that hanger ball 15 is reversibly attached to shaft 11.

Mount 10 has a connector base 28 which is reversibly inserted into the first end 12 of shaft 11. Connector base 28 preferably has holes 29 and 30 on opposite sides of connector base 28 so that a pin 31 can pass through connector base 28 with the ends 32 of pin 31 extending beyond connector base 28. Consequently, the length of pin 31 is greater than the diameter of shaft 11. Alternatively, separate pins 33 and 34, or the same pin 31, may be inserted or screwed into or affixed to holes 29 and 30 without passing all the way through connector base 28. The top surface 35 of connector base 28 may have a threaded opening 36 to engage screw 37. A washer 38 may be positioned between the top surface 35 of connector base 28, the first end 12 of shaft 11, the top end 16 of hanger ball 15, and a magnet 39. The magnet 39 has a central hole 40 so that the magnet 39 can be attached to connector base 28 with screw 37. Washers may also be inserted or positioned in any other areas of the mount 10 as desired.

The second opposite end 13 of shaft 11 has a device or bracket mounting attachment 41, such as a handle bar bicycle mount, attached thereto. A large variety of bicycle mounts are well known in the art. Any suitable type of mounting bracket 42 for hand-held electronic devices can by connected to the device mounting attachment 41. The bicycle mount 41 has a ball joint 44 with a threaded lock connector 68. The second opposite end 13 of shaft 11 may have any suitable type of cap or stopper 43. An alternate bracket mounting attachment 41 having three ball joints 44 is shown in FIG. 14, wherein the attachment 41 can be secured to the second end 13 of support shaft 11.

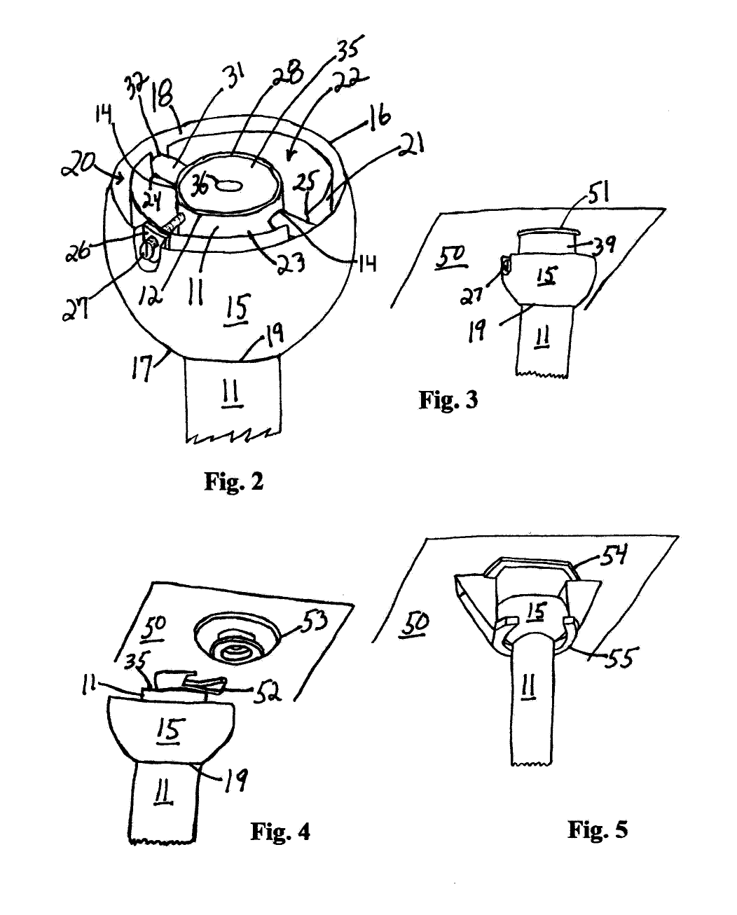

FIG. 2 shows an enlarged view of hanger ball 15 positioned on shaft 11 and engaging pin 31 which passes through shaft 11 and connector base 28. The shaft 11 is first inserted into opening 19 and passed up through the interior 22 of container 21. Connector base 28 is inserted into shaft 11 at first end 12. Pin 31 is inserted into hole 14 on one side of shaft 11, inserted through connector base 28 through hole 29, out through hole 30 of connector base 28, and then out through hole 14 on the opposite side of shaft 11. Accordingly, the ends 32 of pin 31 extend beyond the holes 14 away from shaft 11. As noted in FIG. 1, separate pins 33 and 34, alternatively, may be inserted into holes 14 in shaft 11 and holes 29 and 30 in connector base 28, or affixed to shaft 11 or connector base 28, so that pins 33 and 34 extend away from shaft 11. Hanger ball 15 may then be moved towards the first end 12 of shaft 11 until the slots 24 and 25 in container 21 engage the pin 31 (or pins 33 and 34). The screw 27 may be turned until it engages shaft 11 to hold hanger ball 15 in place on shaft 11. The magnet 39 can be attached to connector base 28 for reversibly securing the shaft 11 to a ceiling or other flat surface.

FIG. 3 shows the mount 10 attached to a ceiling 50 by the magnet 39 attaching magnetically to a magnetically interactive material, such as metal washer 51, which is fixed to the ceiling 50. Mount 10 is easily removed from the metal washer 51 by pulling down on shaft 11. Other connector devices can be used besides a magnet. FIG. 4 shows a female connector 52 attached to the top surface 35 of connector base 28 and a matching male connector 53 fixed to the ceiling 50. The male connector 53 is easily inserted into the female connector 52 to suspend shaft 11 from the ceiling 50. Shaft 11 is easily removed from the ceiling 50 by sliding the male connector 53 horizontally out of the female connector 52. As is known in the art, the male connector 53 can also be placed on the top surface 35 of connector base 28 and the female connector 52 can be fixed to the ceiling 50, if desired. FIG. 5 shows a ceiling bracket 54 fixed to the ceiling 50. Bracket 54 has a semi-circular ring 55 which allows the shaft 11 to pass into the ring 55 and the hanger ball 15 to rest on the ring 55, thereby suspending shaft 11 from the ceiling 50. Shaft 11 is easily removed from the ring 55 by lifting shaft 11 so that the hanger ball 15 is not in contact with the ring 55, and passing the shaft 11 out of the ring 55. In this configuration the pin 31, or pins 33 and 34, may be used with shaft 11 without the use of connector base 28 or magnet 39.

Any suitable type of magnet may be used in the present invention, preferably a neodymium magnet which attaches to a metal contact with 15 to 30 pounds pull-release. Any type of hanger ball can be used. The support shaft may also be used without a hanger ball. Any suitable support shaft may be used. Any type of bicycle handle bar mount may be used, preferably one that uses a swivel ball head which rotates in any direction. Any suitable mounting bracket may be used to attach a device to the handle bar mount.

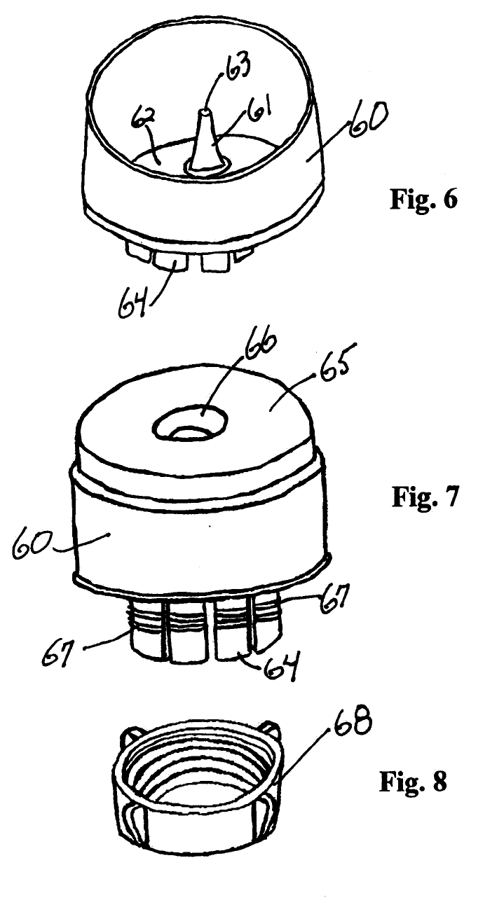

FIGS. 6-9 illustrate an alternative embodiment of the present invention. FIG. 6 shows a cup 60 with a central post 61 within its interior and attached to the interior bottom 62 of the cup 60. The free end of the post 61 has a threaded opening 63 for attaching a magnet. The exterior bottom of the cup 60 has connecting fingers 64.

FIG. 7 shows a magnet 65 placed inside the cup 60. Magnet 65 has a central opening 66 for placing the magnet 65 over the post 61 and attaching the magnet 65 to the post 61 with a screw. Glue or tape, or a combination thereof, may be used on the bottom 62 of cup 60 to further secure the magnet 65 in cup 60. The connecting fingers 64 on the exterior bottom of cup 60 have threads 67.

FIG. 8 shows a threaded lock connector 68 which fits over the connecting fingers 64 and screws onto the threads 67, thereby compressing the connecting fingers 64 together. This type of threaded lock connector 68 is well-known in the art and is used to attach the connecting fingers 64 to a ball joint 44 so that the ball joint 44 is rotatably secured within the connecting fingers 64.

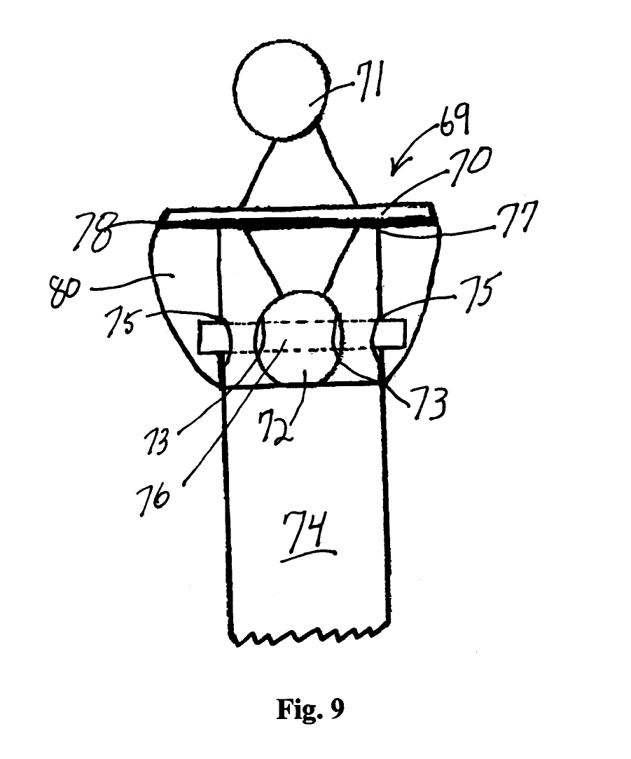

FIG. 9 shows a dual ball joint device 69 having a first ball joint 71 and an opposite second ball joint 72. The ball joints 71 and 72 are attached to a central base 70. Ball joint 72 has openings 73 on each side of ball joint 72 forming a channel through ball joint 72. Ball joint 72 is inserted through the top end 77 of shaft 74. Pin 76 is inserted through an opening 75 in shaft 74, then through the openings 73 in ball joint 72, and then through the other opening 75 in shaft 74 so as to reversibly attach ball joint 72 to shaft 74. A compressible spacer 78 is placed between the base 70 of the ball joint device 69 and the top end 77 of shaft 74 to bias the base 70 away from the top end 77 of shaft 74. This will help secure pin 76 and a hanger ball 80 which may be used to cover the top end 77 of shaft 74 and pin 76.

The threaded lock connector 68, shown in FIG. 8, is placed over the first ball joint 71 and the first ball joint 71 is inserted into the threaded fingers 64 shown in FIG. 7. The threaded lock connector 68 is then screwed onto the threaded fingers 64 which thereby attaches the cup 60 reversibly and rotatably to ball joint 71. In this manner, shaft 74 can rotate freely relative to the cup 60 and magnet 65. The magnet 65 can suspend shaft 74 from a ceiling by attaching to a metal surface on the ceiling. If desired, the shaft 74 can be removed from the second ball joint 72 and a mounting bracket, such as mounting bracket 42 shown in FIG. 1, can be attached directly to ball joint 72, rather than at the bottom end of shaft 74.

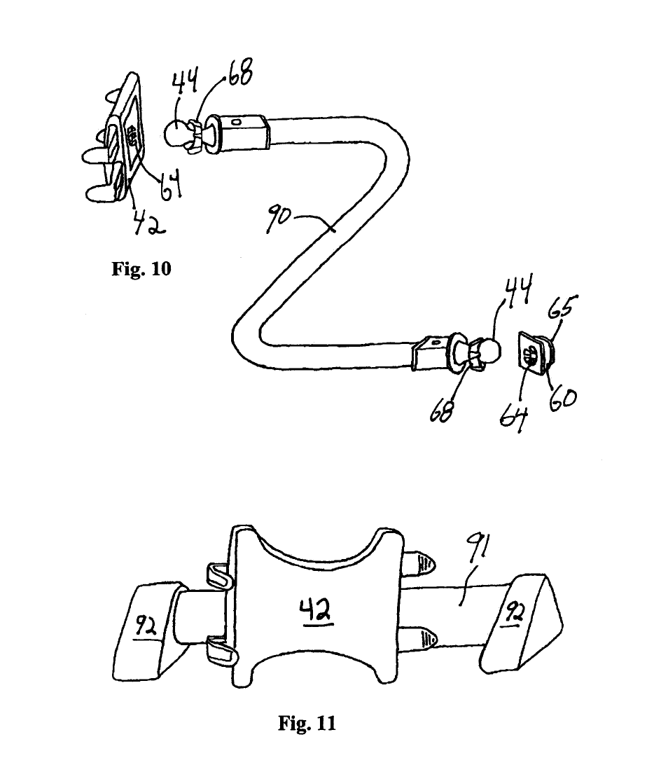

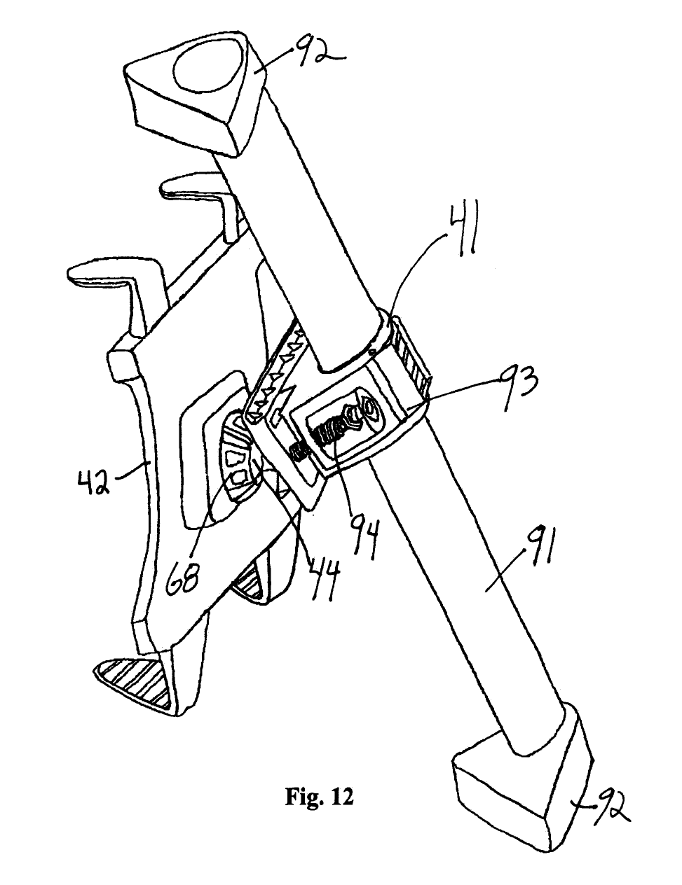

FIGS. 10-12 illustrate alternative embodiments of the shaft 11 shown in FIG. 1. FIG. 10 shows a flexible goose-neck shaft 90, well known in the art, with two opposing ends that each have a ball joint 44. Each ball joint 44 joint has a threaded lock connector 68 which is screwed onto the threaded fingers 64 of the mounting bracket 42 or the cup 60, thereby attaching the shaft 90 reversibly and rotatably to the mounting bracket 42 and the cup 60. The magnet 65 in cup 60 can secure the shaft 90 to any magnetically interactive surface with the shaft 90 extending in any direction desired. FIG. 11 illustrates a shaft 91 with triangular rubber bases 92 supporting shaft 91 in a horizontal position on a flat surface. FIG. 12 illustrates the shaft 91 also being used in a substantially vertical position on a flat surface, thus allowing larger devices to be viewed and supported in a vertical position. FIG. 12 further illustrates the back side of the bicycle mount 41 on shaft 91. Bicycle mount 41 has an adjustable thumb tab lock 93 that secures the bicycle mount 41 to shaft 91 by creating a clamping force on shaft 91. Unlocking thumb tab lock 93 by lifting it up releases the clamping force and opens the bicycle mount 41 for easy upward and downward positioning of bicycle mount 41 along shaft 91. Locking the thumb tab lock 93 by pressing it down creates the clamping force and compresses a spring 94 housed within the bicycle mount 41. The spring 94 biases the bicycle mount 41 to an open position.

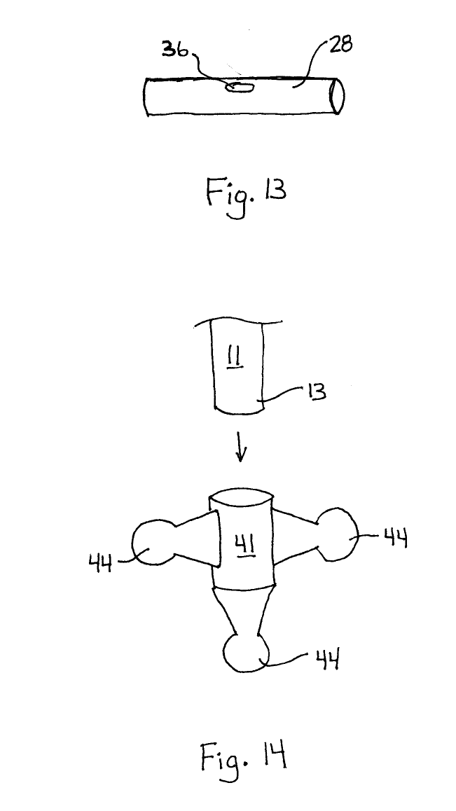

The quick release mount of the present invention can be made of any suitable materials, including metal, plastic, or wood, or a combination thereof. The shaft can hold or support a plurality of accessories and devices at the same time. The connector base can be molded as one piece with extensions, wherein the extensions are functionally equivalent to pins 31 or 33 and 34 when they are inserted into the connector base. An example of an alternate connector base 28 is shown in FIG. 13.

According to one aspect of the present invention, the invention comprises a quick-release mount assembly having a magnet mounted to one end for quickly and releasably securing the mount assembly to a magnetically interactive surface and an adjustable mounting bracket for quickly and releasably holding a variety of electronic devices.

While the invention has been shown and described in some detail with reference to specific exemplary embodiments, there is no intention that the invention be limited to such detail. On the contrary, the invention is intended to include any alternative or equivalent embodiments that fall within the spirit and scope of the invention as described in the following claims.

I claim:

1. A method for holding a smartphone or tablet computer in a reading position attached to a ceiling, wall our counter comprising:
attaching a triple ball joint member to an elongated cylindrical extension member;
coupling the elongated cylindrical extension member telescopically into a tubular receiving member;
attaching the tubular receiving member to a dome-shaped base, the dome-shaped base having a flat bottom containing a magnet;
attaching a smartphone or tablet computer holding clamp having four adjustable fingers to one ball joint on the triple ball joint member, the holding clamp having a ball joint interface on a rear side;
clamping a smartphone or tablet computer in the holding clamp in a configuration with screen facing away from the holding clamp using the four adjustable fingers;
bringing the flat bottom of the dome-shaped base and magnet into contact with a metal ceiling, wall or counter, or if the ceiling, wall or counter is non-metal, attaching a metal plate to the ceiling, wall or counter and bringing the flat base and magnet into contact with the metal plate;
telescoping the extension member in the tubular receiving member to achieve a desired position for the smartphone or tablet computer;
locking the telescoping extension member in the tubular receiving member;
turning on the smartphone or tablet computer for use.

2. The method of claim 1 wherein the smartphone or tablet computer holding clamp has a central ball joint and two side ball joints aligned 90 degrees from the central ball joint.

3. The method of claim 2 comprising attaching the smartphone or tablet computer holding clamp to the center ball joint on the smartphone or tablet computer holding clamp.

4. The method of claim 2 comprising attaching the smartphone or tablet computer holding clamp to one of the side ball joints on the smartphone or tablet computer holding clamp.

5. The method of claim 1 further comprising supplying the elongated cylindrical extension member and the tubular receiving member in a plurality of different lengths.

6. The method of claim 5 wherein the elongated cylindrical extension member and the tubular receiving member are supplied in three different lengths.

7. The method of claim 1 wherein the magnet is removable.

8. The method of claim 1 wherein the dome-shaped base and magnet is attached to a ceiling, and the elongated cylindrical extension member and tubular receiving members are vertical.

9. The method of claim 1 wherein the magnet has 15-35 lbs. pull release.

10. A method for holding a smartphone or tablet computer in a reading position attached to a ceiling, wall our counter comprising:
supplying a triple ball joint member attachable to an elongated cylindrical extension member;
supplying a tubular receiving member adapted to be coupled to the elongated cylindrical extension member telescopically;
supplying a dome-shaped base, the dome-shaped base having a flat bottom containing a magnet attachable to the tubular receiving member;
supplying a smartphone or tablet computer clamp member having four clamp fingers;
supplying a magnetically active flat metal attach member adapted to be attached to a ceiling, wall or counter in order to cooperate with the magnet in the dome-shaped base to hold the tubular receiving member, the elongated cylindrical extension member and the clamp member when the ceiling, wall or counter is non-magnetic.

11. The method of claim 10 wherein the smartphone or tablet computer holding clamp has a central ball joint and two side ball joints aligned 90 degrees from the central ball joint.

12. The method of claim 10 further comprising supplying the elongated cylindrical extension member and the tubular receiving member in a plurality of different lengths.

13. The method of claim 10 wherein the magnet is removable.

14. The method of claim 10 wherein the dome-shaped base and magnet is attached to a ceiling, and the elongated cylindrical extension member and tubular receiving members are vertical.

15. The method of claim 10 wherein the magnet has 15-35 lbs. pull release.
